(19) United States
(12) Patent Application Publication
(10) Pub. No.: US 2002/0182843 A1
(43) Pub. Date: Dec. 5, 2002

(54) Method for connecting semiconductor unit to object via bump

(75) Inventor: Han-Ping Pu, Yunho (TW)

Correspondence Address: KLARQUIST SPARKMAN, LLP, 121 SW SALMON STREET, SUITE 1600, PORTLAND, OR, 97204, US

(73) Assignee: Siliconware Precision Industries Co., Ltd.

(21) Appl. No.: 09/952,651

(22) Filed: Sep. 13, 2001

(30) Foreign Application Priority Data
May 30, 2001 (TW) 90112991

(51) Int. Cl. H01L 21/44

(52) U.S. Cl. 438/615

(57) ABSTRACT

The present invention provides methods for connecting, via at least a bump, at least a semiconductor unit to at least an object such as lead frame or substrate, which methods are characterized by comprising the steps of: forming at least an object bump on the object; contacting the object bump with a chip bump of the chip, with the melting points of the object bump and chip bump different from each other (specifically the melting point of the object bump is selected to be higher than that of the chip bump); and providing heat in such a way that the bump (specifically the chip bump) of lower melting point melts to flow along the surface of the object bump, and to let the object bump contact and connect the chip, resulting in the magnitude of the gap between the chip and the object being determined by the height of the object bump which has remained the same, leading to elimination of problems arising from the disunity of bumps' collapses inherent in conventional arts of connecting a chip to a lead frame or substrate via bumps.

### FIELD OF THE INVENTION

The present invention relates generally to arts of connecting at least a semiconductor unit to at least an object via at least a bump, particularly to arts of connecting at least a chip to at least a lead frame or substrate via at least a bump.

### BACKGROUND OF THE INVENTION

In conventional arts of connecting a chip to a lead frame via bumps, reflow soldering process always results in bumps' collapses of inconsistent height due to disunity of wettability on the surface of the lead frame, and may even lead to the chip contacting the lead frame.

Although U.S. Pat. No. 6,184,573 and Taiwanese patent publication No. 366576 suggested schemes of spreading a solder mask layer on a lead frame and forming openings in the solder mask layer, in order to control collapse height when bumps melt (i.e., to restrict solder flowing), so that bump collapse height may more likely be consistent after reflow soldering. The process of spreading the solder mask layer on the lead frame and forming openings therein, however, is quite complicate and expensive, and the light resolution of solder mask material is so poor that the accuracy promotion of forming openings in the solder mask is not realistic, i.e., the sizes of the openings are unlikely to be consistent. Furthermore, in case the bump is relatively small (bump diameter of 120˜130μ for example), it is even more difficult to form openings with sufficient accuracy. The inaccuracy of the opening size will inevitably result in the inconsistency of the sizes of the openings, leading to inconsistency of collapse of the bumps, and to extreme difficulty of reliably controlling the quality of the electrical connection between the chip and the lead frame. On the other hand, the bumps with inconsistent size of solder joint area provide inconsistent thermal stress due to different thermal expansion coefficient between the chip and the lead frame, resulting in quality uncertainty of a chip package. Although Laser technology may be used to form relatively delicate openings, it must be so implemented as to form the openings one by one, leading to unreasonable time consumption and high manufacturing cost. Even worse is the formation of voids between the chip and the lead frame when molding the chip package, as a result of inconsistent magnitude of the gap between the chip and the lead frame caused by inconsistent collapse of the bumps. The voids contribute to poor reliability of quality of a chip package. It can be seen now that the scheme of forming openings in a solder mask layer on a lead frame according to the two prior arts are still not ideal for packaging chips, and a further better art for connecting a chip to a lead frame via bumps is expected by related industries. The present invention is therefore developed to fulfill the expectation.

Due to the difficulty for conventional arts to provide a chip package with fine pitch which is expected by related industries, as can be understood from the above description, the present invention further discloses a scheme of forming bumps on lead frames by plating technology, in order to realize chip packages with fine pitch.

A Conventional method for connecting a chip to a lead frame via bumps is described hereinafter by referring FIG. 1a and FIG. 1b. As shown in FIG. 1a, chip 21 connects an inner lead 81 of lead frame 101 via bump 31, wherein bump 31 collapses in reflow soldering, with its height 28 shown in FIG. 1a reduced to height 29 shown in FIG. 1b. Furthermore, collapses of different bumps are not consistent due to disunity of wettability on the lead frame. The above Taiwanese patent publication No. 366576 and U.S. Pat. No. 6,184,573 disclosed some schemes intended for solutions to the bump collapse or the inconsistency of bump collapses inherent in conventional arts of connecting a chip to a lead frame via bumps. The prior schemes are characterized by spreading a solder mask layer 22 on lead frame 101 (as show in FIG. 1c), and forming opening 23 for bump 31 to contact lead frame 101, in order to restrict the bump collapse. However, the technology to spread the solder mask layer on lead frame 101 is not yet mature, the methods suggested by the two prior arts for connecting chip 21 to lead frame 101 via bumps 31 are far from ideal, leading to the development of the present invention for realizing ideal methods of connecting at least a chip to a lead frame via bumps.

### SUMMARY OF THE INVENTION

An object of the present invention is to provide a solution to the problem of inconsistency of bumps' collapses faced by conventional processes of connecting a chip to a lead frame via bumps.

Another object of the present invention is to provide alternative arts for related industries to avoid high cost and complicated steps resulting from adopting the process of forming openings in solder mask layer which is intended for avoiding the disunity of bumps' collapses when connecting a chip to a lead frame via bumps.

A further object of the present invention is to provide a method of connecting a semiconductor unit to an object via bumps, in which a semiconductor package with fine pitch can be realized by steps featuring stencil printing or plating to form bumps on the object.

Another further object of the present invention is to provide a method of connecting a semiconductor unit to an object via bumps, which features stencil printing or plating for forming, on the object, the bumps with height finely controllable and melting point (melting temperature) higher than that of chip bump, thereby the gap between the semiconductor unit and the object can be determined by the height of the bumps formed on the object, and bumps' collapses can be finely controlled, and molding process for the chip package can be immunized against void formation.

The other further object of the present invention is to provide a method of connecting a semiconductor unit to an object via bumps, which features stencil print or plating for forming bumps on the object, thereby the semiconductor unit connects the object via the bumps formed on the object and having height and/or size finely controllable, resulting in finely controllable solder joint area for ensuring the quality of electrical connection between the semiconductor unit and the object, and for avoiding the unevenness of thermal stress resulting from the difference in thermal expansion coefficient between the semiconductor unit and the object.

The present invention may be represented by a method for connecting at least a semiconductor unit (such as a chip) to at least an object (such as a substrate or lead frame) via at least a bump wherein the semiconductor unit includes at least a bump of a first type. The method representing the present invention may comprise the steps of:

forming at least a bump of a second type on the object wherein the melting point of the bump of the second type is different from that of the bump of the first type;

arranging the semiconductor unit and the object in such a way that the bump of the first type and the bump of the second type face and contact each other; and

providing heat until the bump with lower melting point melts while the bump with higher melting point remains (height and/or size of the bump remains unchanged, for example), the bump with lower melting point melts for the bump with higher melting point to contact and connect the semiconductor unit.

According to the above method provided by the present invention, the bump with higher melting point (melting temperature) does not melt in the step of providing heat, and therefore will not collapse, resulting in the elimination of inconsistency of bumps' collapses inherent in conventional art of connecting a chip to a lead frame via bumps.

In this disclosure, the bump formed on a lead frame is called “lead frame bump”, and the bump of a chip is called “chip bump”.

In current practice of applying the above method in connecting a chip to a lead frame via bump(s), the melting point of the lead frame bump(s) is usually selected to be higher than that of chip bump(s), so that the connection between the chip and the lead frame is actually via the lead frame bump (chip bumps melt while lead frame bumps remain). Because the lead frame bump may be formed by stencil print or plating, its size and height can be finely controlled, i.e., the gap (or distance) which is between the chip and the lead frame and which is determined by the height of the lead frame bump can be finely controlled regardless of the step of providing heat such as reflow soldering which is indispensable to the art of connecting a chip to a lead frame via bump(s).

It can be understood now that the art based on the present invention features:

1. Eliminating the problem of inconsistency of bumps' collapses faced by conventional art of connecting a chip to a lead frame via bumps.

2. Incurring no such problems of high cost and complicated manufacturing process as does the arts which are based on forming openings in a solder mask layer on a lead frame in order to attempt avoiding the inconsistency of bumps' collapses.

3. Forming lead frame bumps by stencil print or plating, thereby at least a chip can be ideally connected to the lead frame through the joint connection of chip bumps and the lead frame bumps, whereby chip packages with fine pitch can be realized.

4. Forming, by stencil print or plating, lead frame bumps with melting point (melting temperature) higher than chip bumps, and with height finely controllable, thereby the gap size between the chip and the lead frame is solely determined by the height of the lead frame bumps, leading to no collapse or finely controlled collapses, immunizing molding process of the chip package against void effect resulting from the inconsistency of bumps' collapses faced by conventional art of connecting a chip to a lead frame via bumps.

5. Forming, by stencil print or plating, lead frame bumps with melting point (melting temperature) higher than chip bumps, and with height as well as size finely controlled, thereby the area of solder joint of each of the lead frame bumps can be finely controlled, leading to reliable quality of electrical connection between the chip and the lead frame, also leading to avoiding unevenness of thermal stress resulting from the difference in thermal expansion coefficient between the chip and the lead frame.

In the above method developed by the present invention, the step of providing heat is to reflow solder the bump of lower melting point. Better wettability between two bumps contacting each other may be achieved by spreading flux on the surface of the bump, thereby better reflow soldering can be achieved. The way for two bumps to face and contact each other in the method developed by the present invention is not necessarily limited to vertical direction, it may also be in horizontal direction such as left-right, or in any direction as long as the following condition stands: the bump of lower melting point melts and flows along the surface of the bump of higher melting point during the step of reflow soldering, resulting in the bump of higher melting point being surrounded by the melted bump of lower melting point (the bump of higher melting point does not melt), thereby the semiconductor unit and the object are eventually connected by the bump of higher melting point. In case the direction for two bumps to face and contact each other is vertical (i.e., one is on the top of the other), the force due to gravity of the one on the top (i.e., the weight of the one on the top) naturally serves as a force for the two bumps to contact each other with pressure, leading to the bump (not melted) of higher melting point being gradually surrounded by the bump of lower melting point when the bump of lower melting point is melting, without need of another external force. In case the direction for the two bumps to contact is not vertical, an external force may be applied in such a way that the melted bump gradually flows along the surface of the bump (not melted) of higher melting point, until the semiconductor unit and the object are connected by the bump of higher melting point.

In the above method developed by the present invention, the semiconductor unit may include a semiconductor connection surface with the bump of first type seated thereon, and the object may include an object connection surface with the bump of second type seated thereon. An external force may be applied in such a way that the bump of first type and the bump of second type face and contact each other, with the semiconductor connection surface and the object connection surface face and approximately parallel each other.

Based on the method provided by the present invention, at least two semiconductor units (such as chips) may be connected to an object (such as lead frame or substrate) via bumps. Assume the semiconductor unit includes at least a bump of first type (such as a chip bump) with a first temperature value as its melting point, and the object includes a first object connection surface and a second object connection surface wherein the first object connection surface and the second object connection surface are in different direction (one is upward while the other downward, for example), the method provided by the present invention for connecting at least two such semiconductor units to an object via bumps may comprise the step of:

forming at least a bump of second type (such as the aforementioned lead frame bump) respectively on the first object connection surface and the second object connection surface, wherein the melting point of the bump of second type is a second temperature value different from the first temperature value;

arranging these semiconductor units and the object in such a way that the bumps of first type of these semiconductor units respectively face and contact the bumps of second type of the first object connection surface and the second object connection surface, i.e., the bump(s) of first type of a semiconductor unit face(s) and contact(s) the bump(s) of second type of the first object connection surface while the bump(s) of first type of another semiconductor unit face(s) and contact(s) the bump(s) of second type of the second object connection surface; and

providing heat (executing reflow soldering, for example) in such a way that the temperature of the bump(s) with lower melting point (or the temperature of the reflow soldering) reaches at least the lower one among the first temperature value and the second temperature value, i.e., heat is so provided that the bump(s) with lower melting point melt(s) while the bump(s) with higher melting point remain(s), thereby the bump with lower melting point melts to flow along the surface of the bump with higher melting point, whereby the melted bump gradually surrounds the bump of higher melting point. If a force is applied in such a way that the semiconductor units tend to move toward the object, the bump with lower melting point will disperse more quickly to flow along the surface of the bump which remains due to its higher melting point. According to the art provided by the present invention, the bump with higher melting point shall not collapse because it does not melt as a result of its higher melting point which is higher than the temperature reached by providing heat, leading to elimination of problems arising from disunity of bumps' collapses inherent in conventional art of connecting a semiconductor unit to an object via bump(s).

A method further provided by the present invention for connecting at least a semiconductor unit (such as a chip) to an object (such as a lead frame or a substrate) may comprise the steps of:

forming at least an object bump on the object;

arranging the object, the semiconductor unit, and a connection medium in such a way that the connection medium is sandwiched between the object bump and the semiconductor unit, wherein the melting point of the connection medium is lower than that of the object bump and the semiconductor unit; and

providing heat in such a way that the connection medium melts while the object bump and the semiconductor unit remain, until the object bump contacts and connects the semiconductor unit.

Obviously the method provided by the present invention for connecting a semiconductor unit (such as a chip) to an object (such as a lead frame or a substrate) via bump(s) may also be embodied in a way similar to the above steps: forming at least a chip bump on a chip (required only if no chip bump has been formed on the chip), sandwiching a connection medium between the chip bump and the object, and providing heat in such a way that the connection medium melts while the chip bump and the object do not melt, until the chip bump and the object are connected as a result of the melting of the connection medium.

The present invention may best be understood through the following description with reference to the accompanying drawings, in which:

### BRIEF DESCRIPTION OF THE DRAWINGS

FIGS. 1a and 1b show a typical conventional art of connecting a chip to a lead frame via at least a bump.

FIGS. 2 ˜6 show an embodiment of a method provided by the present invention for connecting a semiconductor unit to an object via a bump.

FIGS. 7a and 7b show an embodiment of a method provided by the present invention for connecting at least two semiconductor units to an object via bumps.

FIGS. 8 ˜12 show a further embodiment of a method provided by the present invention for connecting a semiconductor unit to an object via at least a bump.

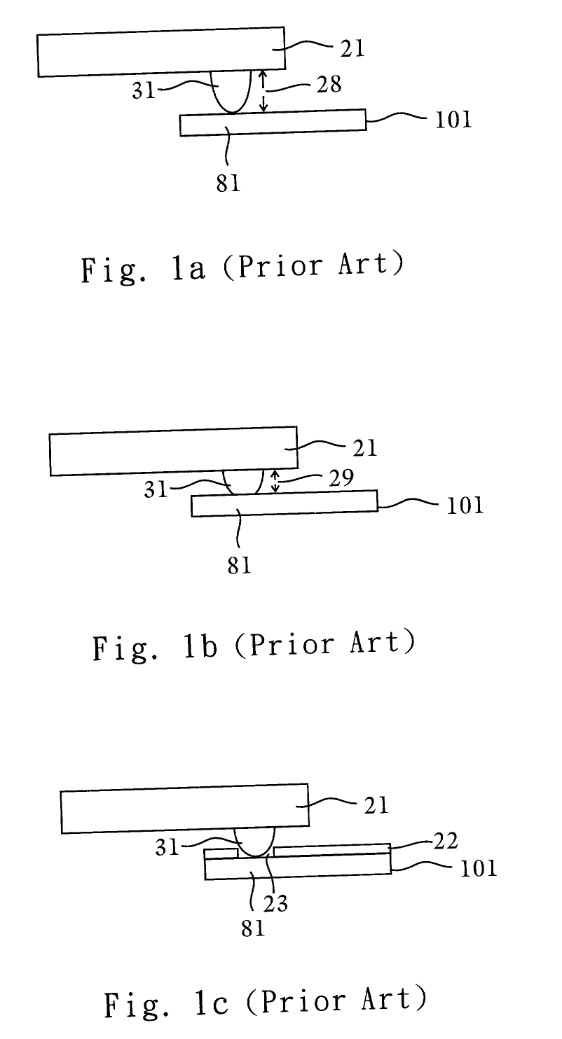

### DETAILED DESCRIPTION OF THE PREFERRED EMBODIMENTS

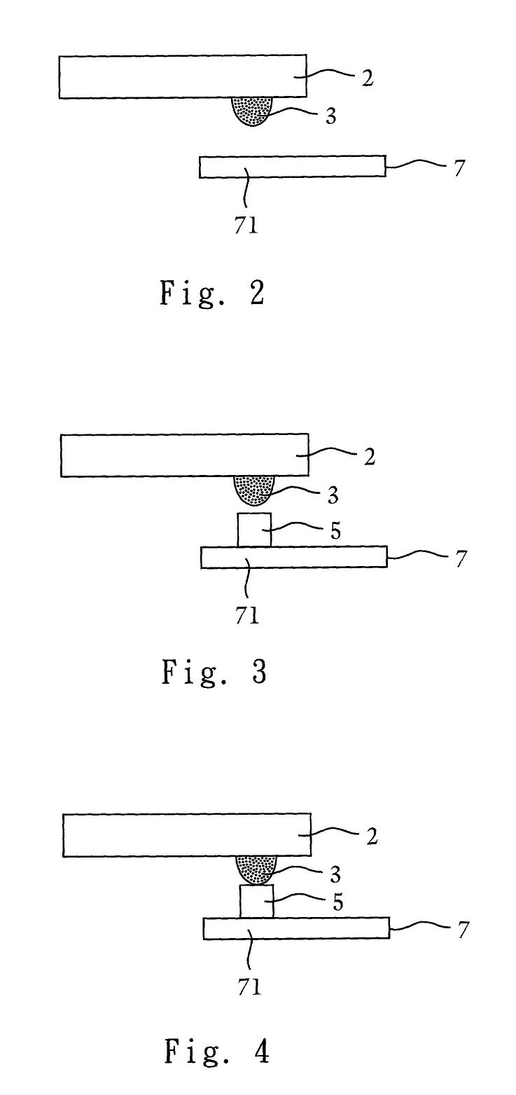

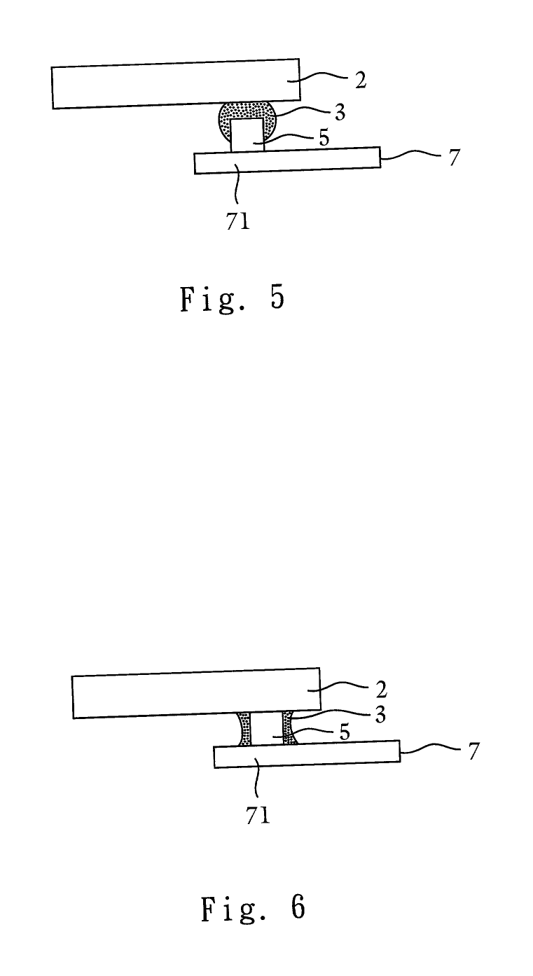

FIGS. 2 ˜6 show a first embodiment of the method provided by the present invention for connecting a semiconductor unit (such as chip 2 in the figures) to an object (such as lead frame 7 in the figures) via bump 3 (such as alloy of 63 tin/37 lead, with melting point of 183° C.). The first embodiment of the method comprises the following steps:

forming at least a bump 5 (such as alloy of 90 lead/10 tin, with melting point of 220° C., which is shown in FIG. 3) on the inner lead 71 of lead frame 7 wherein the melting point of the bump 5 is higher than that of the bump 3;

arranging the semiconductor unit and the object in such a way that the bump 3 and the bump 5 face and contact each other; and

providing heat (reflow soldering the bump of lower melting point, i.e., reflow soldering bump 3, for example) until bump 3 melts as a result of the temperature of bump 3 (or the temperature of the reflow soldering) reaching the melting point of bump 3, while the temperature of bump 5 (or the temperature of the reflow soldering) remains below the melting point of bump 5 and bump 5 does not melt, thereby bump 3 melts to flow along the surface of bump 5 and to gradually surround surface of the bump 5, while one end of bump 5 contacts and connects chip 2 when bump 3 is fully melted, resulting in the magnitude of the gap between chip 2 and lead frame 7 being determined by the size (height) of bump 5 which has not melted (actually it may remain the same in shape), therefore resulting in avoidance of problems arising from bump collapse, leading to elimination of problems arising from the disunity of bumps'collapses inherent in conventional arts of connecting a chip to an object (such as a lead frame) via bumps. Obviously bump 5 may be in permanent connection with chip 2 when the melted bump 3 gets cool as a result of ending the step of providing heat. In other words, bump 3 melts for bump 5 to approach chip 2, and to eventually contact and connect chip 2, and further to be in permanent connection with chip 2 when melted bump 3 gets cool.

According to the method provided by the present invention for connecting a semiconductor unit to an object via bump, the solder wettability between the bump on the semiconductor unit's side and the bump on the object's side is essentially controlled by the bump of higher melting point, and the bump of higher melting point does not melt and shall not collapse, leading to the elimination of problems resulting from the disunity of bumps' collapses inherent in conventional art of connecting a semiconductor unit (such as a chip) to an object (such as a lead frame or a substrate) via bumps.

In the method provided by the present invention for connecting at least a semiconductor unit to an object via bumps, the joint connection between bump 3 and bump 5 will be much better if soldering flux is spread on the surface of at least one of bumps 3 and 5. The spreading of soldering flux may be done before bumps 3 and 5 contact each other.

In the above method provided by the present invention for connecting at least a semiconductor unit to an object (such as a lead frame or substrate) via bumps, lead frame with fine pitch can be achieved if the bump on the lead frame 7 is formed by plating, thereby the trend for related industries to minimize product size can be met.

The application of the method provided by the present invention for connecting at least a semiconductor unit to an object via bumps is not limited to the connection between a chip 2 and a lead frame 7. In fact, the method provided by the present invention can be applied to the connection between a plurality of semiconductor units and a plurality of objects respectively via at least a bump, subjecting to only one condition: the semiconductor unit includes at least one bump of first type, and the object is such that at least one bump with melting point different from that of the bump of first type can be formed thereon.

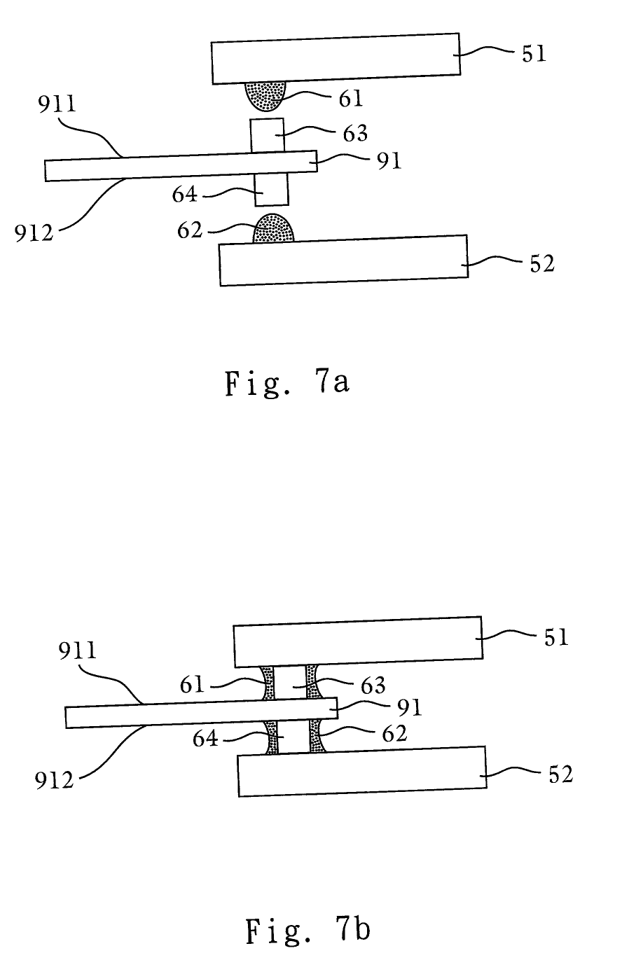

FIGS. 7a and 7b show an embodiment of a method provided by the present invention for connecting at least two semiconductor units (such as chips 51 and 52 in the figures) to an object (such as lead frame 91 in the figures) respectively via bumps (such as chip bumps 61 and 62), which comprises the steps of:

respectively forming lead frame bumps 63 and 64 on a first connection surface 911 and a second connection surface 912 of the lead frame 91, wherein the melting points of lead frame bumps 63 and 64 are respectively higher than those of chip bumps 61 and 62;

arranging the chips 51 and 52 and the lead frame 91 in such a way that the lead frame bumps 63 and 64 respectively face and contact the chip bumps 61 and 62 ;and

providing heat (reflow soldering chip bumps 61 and 62, for example) in such a way that the temperatures of chip bumps 61 and 62 respectively reaches (or the temperature of the reflow soldering reaches) at least the melting points of chip bumps 61 and 62, while the temperatures of bumps 63 and 64 respectively remains (or the temperature of the reflow soldering remains) below the melting points of bumps 63 and 64, thereby bumps 63 and 64 will gradually be surrounded respectively by the melted bumps 61 and 62, and may respectively contact and connect the chips 51 and 52 when the bumps 61 and 62 are fully melted as a result of providing heat thereto. Obviously bumps 63 and 64 may be in permanent connection respectively with chips 51 and 52 when the melted bumps 61 and 62 get cool as a result of ending the step of providing heat. In other words, bumps 61 and 62 melt for bumps 63 and 64 to respectively approach chips 51 and 52, and eventually contact and connect chips 51 and 52. The distances between the lead frame 91 and the two semiconductor units (chips 51 and 52 in this case) are respectively determined by the heights of the lead frame bumps 63 and 64 which have not melted or have remained the same, resulting in avoidance of problems arising from bump collapse, leading to elimination of problems arising from the disunity of bumps' collapses inherent in conventional arts of connecting chips to an object (such as lead frame or substrate) via bumps.

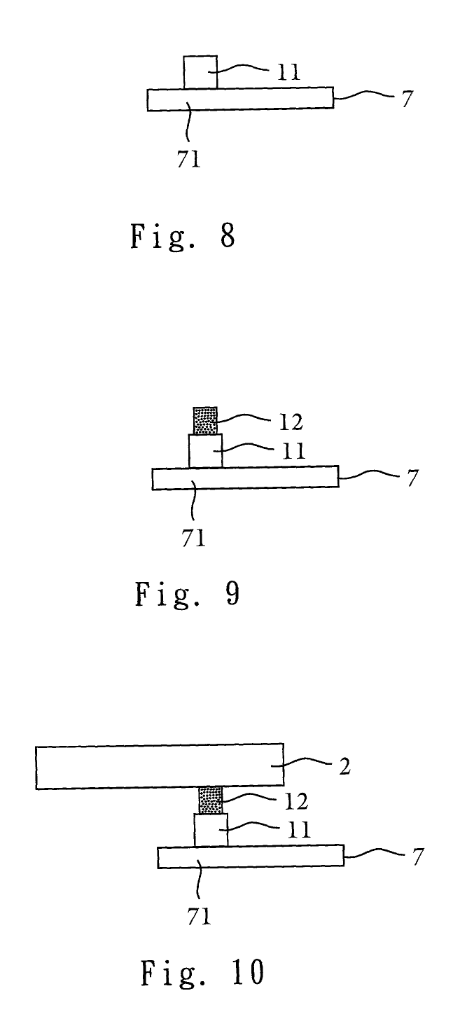

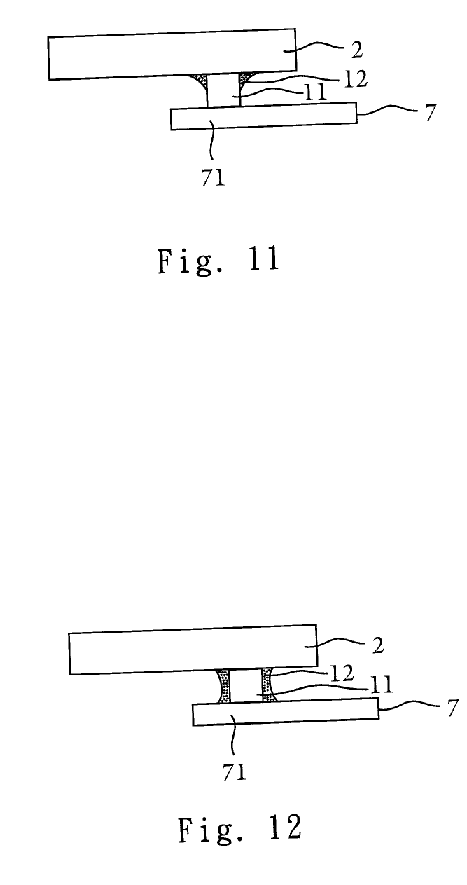

FIGS. 8, 9, 10, 11, 12 show a further embodiment of a method provided by the present invention for connecting a semiconductor unit (such as chip 2 in FIG. 10) to an object (such as lead frame 7 in the figures) via at least a bump, which comprises the steps of:

forming a bump of first type (such as the bump 11 in FIG. 8) on the inner lead 71 of lead frame 7;

placing a connection medium 12 on bump 11 as shown in FIG. 9, followed by arranging a chip 2 in such a way that a portion of the chip 2 for electrical connection (or only for mechanical connection) contacts the connection medium 12, i.e., sandwiching the connection medium 12 between the bump 11 and the chip 2, as shown in FIG. 10; and

providing heat (reflow soldering the connection medium 12, for example) in such a way that the temperature of connection medium 12 (or the temperature of the reflow soldering) reaches at least the melting point of connection medium 12 while the temperatures of bump 11 and chip 2 respectively remains (or the temperature of the reflow soldering remains) below the melting points of bump 11 and chip 2. For example, reflow solder connection medium 12 with a temperature which equals or exceeds the melting point of connection medium 12 while remains below the melting points of bump 11 and chip 2. The connection medium 12 will melt while bump 11 and chip 2 will not melt (actually it may remain the same in shape) under this condition, thereby bump 11 will gradually be surrounded by melted connection medium 12, and may eventually contact and connect chip 2 as shown in FIG. 12, whereby the distance between lead frame 7 and chip 2 is determined by the height of bump 11 which has not melted or has remained the same, resulting in avoidance of problems arising from bump collapse, leading to elimination of problems arising from the disunity of bumps' collapses inherent in conventional arts of connecting a chip to an object (such as lead frame) via bumps.

While the invention has been described on the basis of what are presently considered to be the most practical and preferred embodiments, it shall be understood that the invention is not limited to the disclosure. On the contrary, it is intended to cover various modifications and similar arrangements included within the spirit and scope of the claims which are to be construed with broadest interpretation so as to encompass various modifications and similar structures.

What is claimed is:

1. A method for connecting at least a semiconductor unit to at least an object via at least a bump wherein said semiconductor unit includes at least a bump of a first type, said method comprising the steps of:
forming at least a bump of a second type on said object wherein the melting point of the bump of said second type is higher than that of the bump of said first type;
arranging said semiconductor unit and said object in such a way that the bump of said first type and the bump of said second type face and contact each other; and
providing heat until the bump of said first type melts while the bump of said second type remains, the bump of said first type melts for the bump of said second type to contact and connect said semiconductor unit.

2. The method according to claim 1 wherein the bump of said first type is an alloy including more tin than lead while the bump of said second type is an alloy including more lead than tin.

3. The method according to claim 1 wherein the bump of said first type is an alloy of which 63 percentage is tin and 37 percentage is lead, while the bump of said second type is an alloy of which 90 percentage is lead and 10 percentage is tin.

4. The method according to claim 1 wherein the bump of said second type is formed by plating.

5. The method according to claim 1 wherein the step of providing heat is reflow soldering the bump of said first type.

6. The method according to claim 1 wherein said object is selected from among a substrate and a lead frame.

7. The method according to claim 1 wherein the bump of said first type and the bump of said second type contact each other in such a way that one is over the other.

8. The method according to claim 1 further comprising a step of applying
a force in such a way that the bump of said first type and the bump of said second type contact each other tightly with pressure.

9. The method according to claim 8 wherein the bump of said first type and the bump of said second type contact each other in such a way that one is over the other, and said force originates from gravity.

10. The method according to claim 1 further comprising a step of applying a force in such a way that the bump of said second type and said semiconductor unit tend to approach each other when the bump of said first type melts.

11. The method according to claim 1 wherein said heat is provided in such a way that the temperature of the bump of said first type reaches at least the melting point of the bump of said first type while the temperature of the bump of said second type remains below the melting point of the bump of said second type.

12. The method according to claim 1 wherein said heat is provided until the bump of said first type is fully melted and the bump of said second type contacts and connects said semiconductor unit.

13. A method for connecting at least two semiconductor units to at least an object via bumps, wherein said semiconductor unit includes at least a bump of a first type and said object includes a first connection surface and a second connection surface, said method comprising the steps of:
forming, respectively on said first connection surface and said second surface, at least a bump of a second type, the melting point of the bump of said second type being higher than that of the bump of said first type;
arranging said semiconductor units and said object in such a way that the bump of said first type of each said semiconductor unit faces and contacts the bump of said second type on one of the connection surfaces of said object; and
providing heat in such a way that the temperature of the bump of said first type reaches a least the melting point of the bump of said first type while the temperature of the bump of said second type remains below the melting point of the bump of said second type, until the bump of said first type melts for the bump of said second type to contact and connect said semiconductor unit.

14. The method according to claim 13 wherein the bump of said second type is formed by plating.

15. The method according to claim 13 further comprising a step of applying a force in such a way that the bump of said first type and the bump of said second type contact each other with pressure.

16. The method according to claim 13 wherein said object is selected from among a substrate and a lead frame.

17. The method according to claim 16 further comprising a step of applying a force in such a way that the bump of said first type and the bump of said second type contact each other with pressure, said semiconductor units tend to respectively parallel said first connection surface and said second connection surface, and to approach said object when the bump of said first type melts.

18. A method for connecting at least a semiconductor unit to at least an object via at least a bump, comprising the steps of:
forming at least an object bump on said object;
arranging said object, said semiconductor unit, and a connection medium in such a way that the connection medium is sandwiched between said object bump and said semiconductor unit, wherein the melting point of said connection medium is lower than that of said object bump and said semiconductor unit; and
providing heat in such a way that said connection medium melts while said object bump and said semiconductor unit remain, until said object bump contacts and connects said semiconductor unit.

19. The method according to claim 18 further comprising a step of applying a force in such a way that said semiconductor unit and said object bump, when said connection medium melts, approach each other until contact each other.
